(19) United States
(12) Patent Application Publication
(10) Pub. No.: US 2026/0081583 A1
(43) Pub. Date: Mar. 19, 2026

(54) ACOUSTIC WAVE DEVICE WITH BALANCED ELECTRODE REGIONS

(71) Applicant: Skyworks Global Pte. Ltd., Singapore (SG)

(72) Inventors: Kwang Jae Shin, Yongin-si (KR); Myung Hyun Park, Seongnam-si (KR); Yong Woo Jeon, Anseong (KR); Benjamin Paul Abbott, Irvine, CA (US); Stefan Bader, Fort Collins, CO (US)

(21) Appl. No.: 19/330,729

(22) Filed: Sep. 16, 2025

Related U.S. Application Data
(60) Provisional application No. 63/695,677, filed on Sep. 17, 2024.
(60) Provisional application No. 63/695,594, filed on Sep. 17, 2024.
(60) Provisional application No. 63/695,597, filed on Sep. 17, 2024.
(60) Provisional application No. 63/695,759, filed on Sep. 17, 2024.

(51) Int. Cl. H03H 9/205; H03H 9/54

(52) U.S. Cl. CPC H03H 9/205; H03H 9/54

(57) ABSTRACT

An acoustic wave device structure has first and second electrode layers and a piezoelectric layer extending across series and shunt resonator sections. A piezoelectric layer is positioned between the first and second electrode layers. A first mass loading layer extends across the shunt resonator sections and is positioned between the first electrode layer and the piezoelectric layer. A second mass loading layer extends across the shunt resonator sections and at least one of the series resonator sections. The second electrode layer is positioned between the piezoelectric layer and the second mass loading layer.

### CROSS REFERENCE RELATED APPLICATIONS

Any and all applications for which a foreign or domestic priority claim is identified in the Application Data Sheet as filed with the present application are hereby incorporated by reference under 37 CFR 1.57.

### BACKGROUND

### Field

The present disclosure generally relates to acoustic wave devices, and methods for producing acoustic wave devices, and particularly to acoustic wave devices comprising a piezoelectric layer and electrodes.

### Description of Related Art

Acoustic wave device structures comprising a piezoelectric film and electrodes are utilized in many applications such as surface acoustic wave (SAW) and bulk acoustic wave (BAW) components, including BAW and SAW resonators and filters. Such SAW and BAW components and devices rely on piezoelectric films to transfer or store acoustic energy, and their electrical, mechanical, and electro-mechanical properties vary depending on what piezoelectric materials the piezoelectric films comprise and the thickness of the films.

One piezoelectric material that has been widely used in acoustic waved devices, thanks to its manufacturability and performance levels, is aluminium nitride (AlN). In components comprising AlN piezoelectric film, such as SAW and BAW components, the resonant frequency is dependent on the thickness of the AlN film. This means that, in order for such components to support higher frequencies, a thinner AlN film is needed. However, decreasing AlN film thickness leads to a decrease in the piezoelectric coefficient of the filter.

One solution to compensate such loss is to introduce dopants to the AlN piezoelectric material. For example, a decrease in the piezoelectric coefficient accompanied by reducing the piezoelectric film thickness can be compensated for by doping AlN material with Sc, thereby forming a AlScN film. However, the present inventors have appreciated that high dopant concentrations in piezoelectric layers have been shown to lead to a reduction in the quality factor (Q factor).

In order to improve piezoelectric performance of such devices, dopants, such as Scandium (Sc), are used in piezoelectric layers, such as Aluminum Nitride (AlN). However, high dopant concentrations in piezoelectric layers have been shown to lead to a reduction in the Q factor. The Q factor is a measurement of the energy lost in a resonator per oscillation. Therefore, acoustic devices, such as BAW resonators, with a high Q factor lose less energy than those with a lower Q factor.

### SUMMARY

In some aspects, the techniques described herein relate to an acoustic wave device structure, the acoustic wave device structure including: one or more series resonator sections and one or more shunt resonator sections; a first electrode layer extending across the one or more series resonator sections and the one or more shunt resonator sections; a second electrode layer extending across the one or more series resonator sections and the one or more shunt resonator sections; a piezoelectric layer extending across the one or more series resonator sections and the one or more shunt resonator sections, the piezoelectric layer being positioned between the first electrode layer and the second electrode layer; a first mass loading layer extending across at least the one or more shunt resonator sections, the first mass loading layer being positioned between the first electrode layer and the piezoelectric layer; a second mass loading layer extending across at least the one or more shunt resonator sections and at least one of the one or more series resonator sections, the second electrode layer being positioned between the piezoelectric layer and the second mass loading layer.

In some aspects, the techniques described herein relate to an acoustic wave device structure further including a third mass loading layer extending across at least one of the one or more shunt resonator sections, the third mass loading layer being positioned between the first mass loading layer and the piezoelectric layer.

In some aspects, the techniques described herein relate to an acoustic wave device structure further including a third mass loading layer extending across at least one of the one or more shunt resonator sections, the second mass loading layer being positioned between the second electrode layer and third mass loading layer.

In some aspects, the techniques described herein relate to an acoustic wave device structure wherein a first electrode region of the acoustic wave device includes the first electrode layer and the first mass loading layer, and a second electrode region of the acoustic wave device includes the second electrode layer and the second mass loading layer.

In some aspects, the techniques described herein relate to an acoustic wave device structure wherein the thickness of the first electrode region within at least one of the one or more shunt resonator sections and the thickness of the second electrode region within at least one of the one or more shunt resonator sections are identical, or differ by less than 30%.

In some aspects, the techniques described herein relate to an acoustic wave device structure wherein the first electrode layer and the first mass loading layer are made of the same conductive material.

In some aspects, the techniques described herein relate to an acoustic wave device structure wherein the first electrode layer and the first mass loading layer are made of different conductive materials.

In some aspects, the techniques described herein relate to an acoustic wave device structure wherein the second electrode layer and the second mass loading layer are made of the same conductive material.

In some aspects, the techniques described herein relate to an acoustic wave device structure wherein the second electrode layer and the second mass loading layer are made of different conductive materials.

In some aspects, the techniques described herein relate to an acoustic wave device structure wherein the first electrode region and the second electrode region are made of the same conductive material.

In some aspects, the techniques described herein relate to an acoustic wave device structure wherein the first electrode region and the second electrode region are made of different conductive materials.

In some aspects, the techniques described herein relate to an acoustic wave device structure wherein one or more of the first electrode layer, the first mass loading layer, the second electrode layer, and the second mass loading layer include one or more materials having acoustic impedance of at least 30 MRayl.

In some aspects, the techniques described herein relate to an acoustic wave device structure wherein one or more of the first electrode layer, the first mass loading layer, the second electrode layer, and the second mass loading layer include one or more of: W, Ru, Mo, Ir, Os, Pt, Re and any other materials having a higher acoustic impedance than 30 Mrayls.

In some aspects, the techniques described herein relate to an acoustic wave device structure wherein a first electrode region of the acoustic wave device includes the first electrode layer, the first mass loading layer and the third mass loading layer; and a second electrode region of the acoustic wave device includes the second electrode layer and the second mass loading layer.

In some aspects, the techniques described herein relate to an acoustic wave device structure wherein the first electrode region within at least one of the one or more shunt resonator sections and the thickness of the second electrode region within at least one of the one or more shunt resonator sections are identical, or differ by less than 30%.

In some aspects, the techniques described herein relate to an acoustic wave device structure wherein one or more of the first electrode layer, the first mass loading layer, the second electrode layer, and the second mass loading layer are made of the same conductive material.

In some aspects, the techniques described herein relate to an acoustic wave device structure wherein one or more of the first electrode layer, the first mass loading layer, the second electrode layer, and the second mass loading layer are made of different conductive materials.

In some aspects, the techniques described herein relate to an acoustic wave device structure wherein one or more of the first electrode layer, the first mass loading layer, the second electrode layer, and the second mass loading layer include one or more materials having acoustic impedance of at least 30 MRayl.

In some aspects, the techniques described herein relate to an acoustic wave device structure wherein one or more of the first electrode layer, the first mass loading layer, the second electrode layer, and the second mass loading layer include one or more of: W, Ru, Mo, Ir, Os, Pt, Re and any other materials having a higher acoustic impedance than 30 Mrayls.

In some aspects, the techniques described herein relate to an acoustic wave device structure wherein a first electrode region of the acoustic wave device includes the first electrode layer and the first mass loading layer; and a second electrode region of the acoustic wave device includes the second electrode layer, the second mass loading layer, and the third mass loading layer.

In some aspects, the techniques described herein relate to an acoustic wave device structure wherein the first electrode region within at least one of the one or more shunt resonator sections and the thickness of the second electrode region within at least one of the one or more shunt resonator sections are identical, or differ by less than 30%.

In some aspects, the techniques described herein relate to an acoustic wave device structure wherein one or more of the first electrode layer, the first mass loading layer, the second electrode layer, and the second mass loading layer are made of the same conductive material.

In some aspects, the techniques described herein relate to an acoustic wave device structure wherein one or more of the first electrode layer, the first mass loading layer, the second electrode layer, and the second mass loading layer are made of different conductive materials.

In some aspects, the techniques described herein relate to an acoustic wave device structure wherein one or more of the first electrode layer, the first mass loading layer, the second electrode layer, and the second mass loading layer include one or more materials having acoustic impedance of at least 30 MRayl.

In some aspects, the techniques described herein relate to an acoustic wave device structure wherein one or more of the first electrode layer, the first mass loading layer, the second electrode layer, and the second mass loading layer include one or more of: W, Ru, Mo, Ir, Os, Pt, Re and any other materials having a higher acoustic impedance than 30 Mrayls.

In some aspects, the techniques described herein relate to a bulk acoustic wave resonator or filter including the acoustic wave device structure.

In some aspects, the techniques described herein relate to a die including a bulk acoustic wave resonator, the bulk acoustic wave resonator including: one or more series resonator sections and one or more shunt resonator sections; a first electrode layer extending across the one or more series resonator sections and the one or more shunt resonator sections; a second electrode layer extending across the one or more series resonator sections and the one or more shunt resonator sections; a piezoelectric layer extending across the one or more series resonator sections and the one or more shunt resonator sections, the piezoelectric layer being positioned between the first electrode layer and the second electrode layer; a first mass loading layer extending across at least the one or more shunt resonator sections, the first mass loading layer being positioned between the first electrode layer and the piezoelectric layer; a second mass loading layer extending across at least the one or more shunt resonator sections and at least one of the one or more series resonator sections, the second electrode layer being positioned between the piezoelectric layer and the second mass loading layer.

In some aspects, the techniques described herein relate to a filter including one or more bulk acoustic wave resonators, each bulk acoustic wave resonator including: one or more series resonator sections and one or more shunt resonator sections; a first electrode layer extending across the one or more series resonator sections and the one or more shunt resonator sections; a second electrode layer extending across the one or more series resonator sections and the one or more shunt resonator sections; a piezoelectric layer extending across the one or more series resonator sections and the one or more shunt resonator sections, the piezoelectric layer being positioned between the first electrode layer and the second electrode layer; a first mass loading layer extending across at least the one or more shunt resonator sections, the first mass loading layer being positioned between the first electrode layer and the piezoelectric layer; a second mass loading layer extending across at least the one or more shunt resonator sections and at least one of the one or more series resonator sections, the second electrode layer being positioned between the piezoelectric layer and the second mass loading layer.

In some aspects, the techniques described herein relate to a radio-frequency module including: a packaging substrate configured to receive a plurality of devices; and a die mounted on the packaging substrate, the die having a bulk acoustic wave resonator, the bulk acoustic wave resonator including: one or more series resonator sections and one or more shunt resonator sections; a first electrode layer extending across the one or more series resonator sections and the one or more shunt resonator sections; a second electrode layer extending across the one or more series resonator sections and the one or more shunt resonator sections; a piezoelectric layer extending across the one or more series resonator sections and the one or more shunt resonator sections, the piezoelectric layer being positioned between the first electrode layer and the second electrode layer; a first mass loading layer extending across at least the one or more shunt resonator sections, the first mass loading layer being positioned between the first electrode layer and the piezoelectric layer; a second mass loading layer extending across at least the one or more shunt resonator sections and at least one of the one or more series resonator sections, the second electrode layer being positioned between the piezoelectric layer and the second mass loading layer.

In some aspects, the techniques described herein relate to a wireless mobile device including: one or more antennas; and a radio-frequency module that communicates with the one or more antennas, the radio-frequency module having a die including a bulk acoustic wave resonator, the bulk acoustic wave resonator including: one or more series resonator sections and one or more shunt resonator sections; a first electrode layer extending across the one or more series resonator sections and the one or more shunt resonator sections; a second electrode layer extending across the one or more series resonator sections and the one or more shunt resonator sections; a piezoelectric layer extending across the one or more series resonator sections and the one or more shunt resonator sections, the piezoelectric layer being positioned between the first electrode layer and the second electrode layer; a first mass loading layer extending across at least the one or more shunt resonator sections, the first mass loading layer being positioned between the first electrode layer and the piezoelectric layer; a second mass loading layer extending across at least the one or more shunt resonator sections and at least one of the one or more series resonator sections, the second electrode layer being positioned between the piezoelectric layer and the second mass loading layer.

In some aspects, the techniques described herein relate to a method of forming an acoustic device structure, the method including the steps of: forming a first electrode layer on a substrate, the acoustic device structure having two or more sections and the first electrode layer extending across at least a first section and a second section of the two or more sections; forming a first mass loading layer on the first electrode layer, the first electrode layer extending across the second section; forming a piezoelectric layer on the first electrode layer and the first mass loading layer, the piezoelectric layer extending across the first section and the second section, the piezoelectric layer being in contact with the first electrode layer in the first section, and the piezoelectric layer being in contact with the first mass loading layer in the second section; forming a second electrode layer on the piezoelectric layer, the second electrode layer extending across at least the first section and the second section; forming a second mass loading layer on the second electrode layer, the second electrode layer extending across the second section.

In some aspects, the techniques described herein relate to a method wherein the step of forming the first mass loading layer is performed by using an etching process.

In some aspects, the techniques described herein relate to a method wherein the step of forming the first mass loading layer is performed by using a dry etching technique.

In some aspects, the techniques described herein relate to a method wherein the step of forming the first mass loading layer is performed by depositing an initial layer of material(s) forming the first mass loading layer across the first section and the second section, and performing the etching process to remove the initial layer of material(s) from the first section.

In some aspects, the techniques described herein relate to a method wherein the step of forming the first mass loading layer is performed by using a lift-off process.

In some aspects, the techniques described herein relate to a method wherein the step of forming the first mass loading layer is performed by using one or more photolithography techniques.

In some aspects, the techniques described herein relate to a method wherein the step of forming the first mass loading layer is performed by depositing an initial layer of material(s) forming the first mass loading layer across the first section and the second section, and performing the lift-off process to remove the initial layer of material(s) from the first section.

In some aspects, the techniques described herein relate to a method further including the step of removing the substrate from the acoustic device structure.

In some aspects, the techniques described herein relate to a method wherein the substrate is removed by means of milling, lift-off and/or etching.

In some aspects, the techniques described herein relate to a method wherein the acoustic device structure includes one or more sacrificial layers for the milling, lift-off and/or ctching.

In some aspects, the techniques described herein relate to a method wherein the second mass loading layer extends across at least a part of the first section and the second section.

In some aspects, the techniques described herein relate to a method further including the step of forming a third mass loading layer extending across at least a part of the second section, the third mass loading layer being formed after the step of forming the first mass loading layer to be positioned between the first mass loading layer and the piezoelectric layer.

In some aspects, the techniques described herein relate to a method further including the step of forming a third mass loading layer extending across at least a part of the second section, the third mass loading layer being formed after the step of forming the second electrode layer so that the second electrode layer is positioned between the piezoelectric layer and the third mass loading layer.

In some aspects, the techniques described herein relate to a method wherein the first section is configured to function as one or more series resonator sections, and the second section is configured to function as one or more shunt resonator section.

In some aspects, the techniques described herein relate to a method for forming an acoustic wave device, the method including the steps of: forming a first electrode layer of an acoustic device structure on a substrate, the acoustic device structure having two or more sections and the first electrode layer extending across at least a first section and a second section of the two or more sections; forming a first mass loading layer on the first electrode layer, the first electrode layer extending across the second section; forming a piezoelectric layer on the first electrode layer and the first mass loading layer, the piezoelectric layer extending across the first section and the second section, the piezoelectric layer being in contact with the first electrode layer in the first section, and the piezoelectric layer being in contact with the first mass loading layer in the second section; forming a second electrode layer on the piezoelectric layer, the second electrode layer extending across at least the first section and the second section; forming a second mass loading layer on the second electrode layer, the second electrode layer extending across the second section, and forming one or more acoustic wave device components on the acoustic device structure.

In some aspects, the techniques described herein relate to a method wherein the one or more acoustic wave device components are one or more resonator structures.

In some aspects, the techniques described herein relate to a method wherein the one or more acoustic wave device components are one or more bulk acoustic wave device components.

In some aspects, the techniques described herein relate to a method wherein the one or more acoustic wave device components are one or more electrical connections.

In some aspects, the techniques described herein relate to a method wherein the one or more acoustic wave device components are one or more cavity packages.

In some aspects, the techniques described herein relate to an acoustic wave device structure, the acoustic wave device structure including: one or more series resonator sections and one or more shunt resonator sections; a first electrode layer extending across the one or more series resonator sections and the one or more shunt resonator sections; a second electrode layer extending across the one or more series resonator sections and the one or more shunt resonator sections; a piezoelectric layer extending across the one or more series resonator sections and the one or more shunt resonator sections, the piezoelectric layer being positioned between the first electrode layer and the second electrode layer; a first mass loading layer extending across at least the one or more shunt resonator sections, the first electrode layer being positioned between the first mass loading layer and the piezoelectric layer; a second mass loading layer extending across at least the one or more shunt resonator sections and at least one of the one or more series resonator sections, the second electrode layer being positioned between the piezoelectric layer and the second mass loading layer.

In some aspects, the techniques described herein relate to an acoustic wave device structure further including a third mass loading layer extending across at least one of the one or more shunt resonator sections, the third mass loading layer being positioned between the first electrode layer and the piezoelectric layer.

In some aspects, the techniques described herein relate to an acoustic wave device structure further including a third mass loading layer extending across at least one of the one or more shunt resonator sections, the second mass loading layer being positioned between the second electrode layer and third mass loading layer.

In some aspects, the techniques described herein relate to an acoustic wave device structure wherein a first electrode region of the acoustic wave device includes the first electrode layer and the first mass loading layer, and a second electrode region of the acoustic wave device includes the second electrode layer and the second mass loading layer.

In some aspects, the techniques described herein relate to an acoustic wave device structure wherein the thickness of the first electrode region within at least one of the one or more shunt resonator sections and the thickness of the second electrode region within at least one of the one or more shunt resonator sections are identical, or differ by less than 30%.

In some aspects, the techniques described herein relate to an acoustic wave device structure wherein the first electrode layer and the first mass loading layer are made of the same conductive material.

In some aspects, the techniques described herein relate to an acoustic wave device structure wherein the first electrode layer and the first mass loading layer are made of different conductive materials.

In some aspects, the techniques described herein relate to an acoustic wave device structure wherein the second electrode layer and the second mass loading layer are made of the same conductive material.

In some aspects, the techniques described herein relate to an acoustic wave device structure wherein the second electrode layer and the second mass loading layer are made of different conductive materials.

In some aspects, the techniques described herein relate to an acoustic wave device structure wherein the first electrode region and the second electrode region are made of the same conductive material.

In some aspects, the techniques described herein relate to an acoustic wave device structure wherein the first electrode region and the second electrode region are made of different conductive materials.

In some aspects, the techniques described herein relate to an acoustic wave device structure wherein one or more of the first electrode layer, the first mass loading layer, the second electrode layer, and the second mass loading layer include one or more materials having acoustic impedance of at least 30 MRayl.

In some aspects, the techniques described herein relate to an acoustic wave device structure wherein one or more of the first electrode layer, the first mass loading layer, the second electrode layer, and the second mass loading layer include one or more of: W, Ru, Mo, Ir, Os, Pt, Re and any other materials having a higher acoustic impedance than 30 Mrayls.

In some aspects, the techniques described herein relate to an acoustic wave device structure wherein a first electrode region of the acoustic wave device includes the first electrode layer, the first mass loading layer and the third mass loading layer; and a second electrode region of the acoustic wave device includes the second electrode layer and the second mass loading layer.

In some aspects, the techniques described herein relate to an acoustic wave device structure wherein the first electrode region within at least one of the one or more shunt resonator sections and the thickness of the second electrode region within at least one of the one or more shunt resonator sections are identical, or differ by less than 30%.

In some aspects, the techniques described herein relate to an acoustic wave device structure wherein one or more of the first electrode layer, the first mass loading layer, the second electrode layer, and the second mass loading layer are made of the same conductive material.

In some aspects, the techniques described herein relate to an acoustic wave device structure wherein one or more of the first electrode layer, the first mass loading layer, the second electrode layer, and the second mass loading layer are made of different conductive materials.

In some aspects, the techniques described herein relate to an acoustic wave device structure wherein one or more of the first electrode layer, the first mass loading layer, the second electrode layer, and the second mass loading layer include one or more materials having acoustic impedance of at least 30 MRayl.

In some aspects, the techniques described herein relate to an acoustic wave device structure wherein one or more of the first electrode layer, the first mass loading layer, the second electrode layer, and the second mass loading layer include one or more of: W, Ru, Mo, Ir, Os, Pt, Re and any other materials having a higher acoustic impedance than 30 Mrayls.

In some aspects, the techniques described herein relate to an acoustic wave device structure wherein a first electrode region of the acoustic wave device includes the first electrode layer and the first mass loading layer; and a second electrode region of the acoustic wave device includes the second electrode layer, the second mass loading layer, and the third mass loading layer.

In some aspects, the techniques described herein relate to an acoustic wave device structure wherein the first electrode region within at least one of the one or more shunt resonator sections and the thickness of the second electrode region within at least one of the one or more shunt resonator sections are identical, or differ by less than 30%.

In some aspects, the techniques described herein relate to an acoustic wave device structure wherein one or more of the first electrode layer, the first mass loading layer, the second electrode layer, and the second mass loading layer are made of the same conductive material.

In some aspects, the techniques described herein relate to an acoustic wave device structure wherein one or more of the first electrode layer, the first mass loading layer, the second electrode layer, and the second mass loading layer are made of different conductive materials.

In some aspects, the techniques described herein relate to an acoustic wave device structure wherein one or more of the first electrode layer, the first mass loading layer, the second electrode layer, and the second mass loading layer include one or more materials having acoustic impedance of at least 30 MRayl.

In some aspects, the techniques described herein relate to an acoustic wave device structure wherein one or more of the first electrode layer, the first mass loading layer, the second electrode layer, and the second mass loading layer include one or more of: W, Ru, Mo, Ir, Os, Pt, Re and any other materials having a higher acoustic impedance than 30 Mrayls.

In some aspects, the techniques described herein relate to a bulk acoustic wave resonator or filter including the acoustic wave device structure.

In some aspects, the techniques described herein relate to a die including a bulk acoustic wave resonator, the bulk acoustic wave resonator including: one or more series resonator sections and one or more shunt resonator sections; a first electrode layer extending across the one or more series resonator sections and the one or more shunt resonator sections; a second electrode layer extending across the one or more series resonator sections and the one or more shunt resonator sections; a piezoelectric layer extending across the one or more series resonator sections and the one or more shunt resonator sections, the piezoelectric layer being positioned between the first electrode layer and the second electrode layer; a first mass loading layer extending across at least the one or more shunt resonator sections, the first electrode layer being positioned between the first mass loading layer and the piezoelectric layer; a second mass loading layer extending across at least the one or more shunt resonator sections and at least one of the one or more series resonator sections, the second electrode layer being positioned between the piezoelectric layer and the second mass loading layer.

In some aspects, the techniques described herein relate to a filter including one or more bulk acoustic wave resonators, each bulk acoustic wave resonator including: one or more series resonator sections and one or more shunt resonator sections; a first electrode layer extending across the one or more series resonator sections and the one or more shunt resonator sections; a second electrode layer extending across the one or more series resonator sections and the one or more shunt resonator sections; a piezoelectric layer extending across the one or more series resonator sections and the one or more shunt resonator sections, the piezoelectric layer being positioned between the first electrode layer and the second electrode layer; a first mass loading layer extending across at least the one or more shunt resonator sections, the first electrode layer being positioned between the first mass loading layer and the piezoelectric layer; a second mass loading layer extending across at least the one or more shunt resonator sections and at least one of the one or more series resonator sections, the second electrode layer being positioned between the piezoelectric layer and the second mass loading layer.

In some aspects, the techniques described herein relate to a radio-frequency module including: a packaging substrate configured to receive a plurality of devices; and a die mounted on the packaging substrate, the die having a bulk acoustic wave resonator, the bulk acoustic wave resonator including: one or more series resonator sections and one or more shunt resonator sections; a first electrode layer extending across the one or more series resonator sections and the one or more shunt resonator sections; a second electrode layer extending across the one or more series resonator sections and the one or more shunt resonator sections; a piezoelectric layer extending across the one or more series resonator sections and the one or more shunt resonator sections, the piezoelectric layer being positioned between the first electrode layer and the second electrode layer; a first mass loading layer extending across at least the one or more shunt resonator sections, the first electrode layer being positioned between the first mass loading layer and the piezoelectric layer; a second mass loading layer extending across at least the one or more shunt resonator sections and at least one of the one or more series resonator sections, the second electrode layer being positioned between the piezoelectric layer and the second mass loading layer.

In some aspects, the techniques described herein relate to a wireless mobile device including: one or more antennas; and a radio-frequency module that communicates with the one or more antennas, the radio-frequency module having a die including a bulk acoustic wave resonator, the bulk acoustic wave resonator including: one or more series resonator sections and one or more shunt resonator sections; a first electrode layer extending across the one or more series resonator sections and the one or more shunt resonator sections; a second electrode layer extending across the one or more series resonator sections and the one or more shunt resonator sections; a piezoelectric layer extending across the one or more series resonator sections and the one or more shunt resonator sections, the piezoelectric layer being positioned between the first electrode layer and the second electrode layer; a first mass loading layer extending across at least the one or more shunt resonator sections, the first electrode layer being positioned between the first mass loading layer and the piezoelectric layer; a second mass loading layer extending across at least the one or more shunt resonator sections and at least one of the one or more series resonator sections, the second electrode layer being positioned between the piezoelectric layer and the second mass loading layer.

In some aspects, the techniques described herein relate to a method of forming an acoustic device structure, the method including the steps of: forming a first mass loading layer on a substrate, the acoustic device structure having two or more sections and the first mass loading layer extending across the second section of the two or more sections; forming a first electrode layer on the substrate and the first mass loading layer, the first electrode layer extending across a first section and the second section of the two or more sections, the first electrode layer being in contact with the substrate in the first section, and the first electrode layer being in contact with the first mass loading layer in the second section; forming a piezoelectric layer on the first electrode layer, the piezoelectric layer extending across the first section and the second section, the piezoelectric layer being in contact with the first electrode layer in the first section and the second section; forming a second electrode layer on the piezoelectric layer, the second electrode layer extending across at least the first section and the second section; forming a second mass loading layer on the second electrode layer, the second electrode layer extending across the second section.

In some aspects, the techniques described herein relate to a method wherein the step of forming the first mass loading layer is performed by using an etching process.

In some aspects, the techniques described herein relate to a method wherein the step of forming the first mass loading layer is performed by using a dry etching technique.

In some aspects, the techniques described herein relate to a method wherein the step of forming the first mass loading layer is performed by depositing an initial layer of material forming the first mass loading layer across the first section and the second section, and performing the etching process to remove the initial layer of material(s) from the first section.

In some aspects, the techniques described herein relate to a method wherein the step of forming the first mass loading layer is performed by using a lift-off process.

In some aspects, the techniques described herein relate to a method wherein the step of forming the first mass loading layer is performed by using one or more photolithography techniques.

In some aspects, the techniques described herein relate to a method wherein the step of forming the first mass loading layer is performed by depositing an initial layer of material(s) forming the first mass loading layer across the first section and the second section, and performing the lift-off process to remove the initial layer of material(s) from the first section.

In some aspects, the techniques described herein relate to a method further including the step of removing the substrate from the acoustic device structure.

In some aspects, the techniques described herein relate to a method wherein the substrate is removed by means of milling, lift-off and/or etching.

In some aspects, the techniques described herein relate to a method wherein the acoustic device structure includes one or more sacrificial layers for the milling, lift-off and/or etching.

In some aspects, the techniques described herein relate to a method wherein the second mass loading layer extends across at least a part of the first section and the second section.

In some aspects, the techniques described herein relate to a method further including the step of forming a third mass loading layer extending across at least a part of the second section, the third mass loading layer being formed after the step of forming the first mass loading layer to be positioned between the first mass loading layer and the piezoelectric layer.

In some aspects, the techniques described herein relate to a method further including the step of forming a third mass loading layer extending across at least a part of the second section, the third mass loading layer being formed after the step of forming the second electrode layer so that the second electrode layer is positioned between the piezoelectric layer and the third mass loading layer.

In some aspects, the techniques described herein relate to a method wherein the first section is configured to function as one or more series resonator sections, and the second section is configured to function as one or more shunt resonator section.

In some aspects, the techniques described herein relate to a method for forming an acoustic wave device, the method including the steps of: forming a first electrode layer of an acoustic device structure on a substrate, the acoustic device structure having two or more sections and the first electrode layer extending across at least a first section and a second section of the two or more sections; forming a first mass loading layer on the first electrode layer, the first electrode layer extending across the second section; forming a piezoelectric layer on the first electrode layer and the first mass loading layer, the piezoelectric layer extending across the first section and the second section, the piezoelectric layer being in contact with the first electrode layer in the first section, and the piezoelectric layer being in contact with the first mass loading layer in the second section; forming a second electrode layer on the piezoelectric layer, the second electrode layer extending across at least the first section and the second section; forming a second mass loading layer on the second electrode layer, the second electrode layer extending across the second section, and forming one or more acoustic wave device components on the acoustic device structure.

In some aspects, the techniques described herein relate to a method wherein the one or more acoustic wave device components are one or more resonator structures.

In some aspects, the techniques described herein relate to a method wherein the one or more acoustic wave device components are one or more bulk acoustic wave device components.

In some aspects, the techniques described herein relate to a method wherein the one or more acoustic wave device components are one or more electrical connections.

In some aspects, the techniques described herein relate to a method wherein the one or more acoustic wave device components are one or more cavity packages.

Embodiments disclosed herein may address various problems. One or more embodiments may address one or more of the problems concerning the Q factor in an acoustic wave device, such as a BAW, and/or manufacturing of such an acoustic wave device.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 illustrates an circuit diagram of a known exemplary acoustic device, and simplified cross-sectional diagrams of known exemplary series and shunt resonators;

FIG. 2A is a schematic cross-sectional diagram of a known exemplary acoustic device structure comprising series and shunt resonators sections;

FIG. 2B is a schematic cross-sectional diagram of an exemplary acoustic device structure comprising series and shunt resonator sections according to an embodiment;

FIG. 2C is a schematic cross-sectional diagram of an exemplary acoustic device structure comprising series and shunt resonator sections according to an embodiment;

FIG. 2D illustrates (A) a schematic cross-sectional diagram of an exemplary acoustic device comprising an acoustic device structure, (B) a schematic cross-sectional diagram of a known exemplary acoustic device structure, and (C) a schematic cross-sectional diagram of a known exemplary acoustic device;

FIG. 2E is simplified schematic cross-sectional diagrams of a known exemplary acoustic device (left) and an exemplary acoustic device structure comprising series and shunt resonator sections according to an embodiment (right);

FIG. 3A is a schematic flow diagrams illustrating an exemplary dry-etch process that may be used to from one or more parts of the acoustic wave device structure comprising one or more electrode layers and one or more mass loading layers;

FIG. 3B is a schematic flow diagrams illustrating an exemplary lift-off process that may be used to from one or more parts of the acoustic wave device structure comprising one or more electrode layers and one or more mass loading layers;

FIG. 4A is a flow diagram illustrating exemplary steps for manufacturing the acoustic wave device structure using dry-etch process according to an embodiment;

FIG. 4B is a flow diagram illustrating exemplary steps for manufacturing the acoustic wave device structure using lift-off process according to an embodiment;

FIG. 5A is a capacity vs frequency plot illustrating overtone modes of a known exemplary acoustic wave device;

FIG. 5B is a capacity vs frequency plot illustrating overtone modes of an exemplary acoustic wave device according to an embodiment;

FIG. 6A is a plot illustrating frequency responses of an exemplary acoustic wave device according to an embodiment;

FIG. 6 B illustrate Q (top) and Kt2 (bottom) of an exemplary acoustic wave device according to an embodiment and known exemplary acoustic wave devices;

FIG. 7 is a filter according to aspects of the present invention;

FIG. 8 is a radio-frequency front end module according to aspects of the present invention; and

FIG. 9 is a wireless device according to aspects of the present invention.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Generally embodiments of the invention may provide an acoustic wave device comprising a piezoelectric layer and electrodes, and particularly a BAW device comprising a piezoelectric layer and electrodes. A corresponding method of forming such an acoustic wave device is also provided.

A BAW resonator typically has a form of a parallel plate capacitor which comprise conductive layers (e.g. metal electrodes) and a piezoelectric layer. Such resonators are key components in RF filters. Enhancing the Q factor at resonance frequency is crucial in BAW resonators. Typically, larger mass load structures are placed around one electrode to reduce acoustic wave dissipation and improve Q factor.

The terms “growth” and “deposition”, and “grown” and “deposited” may be used interchangeably for the purpose of the following discussion.

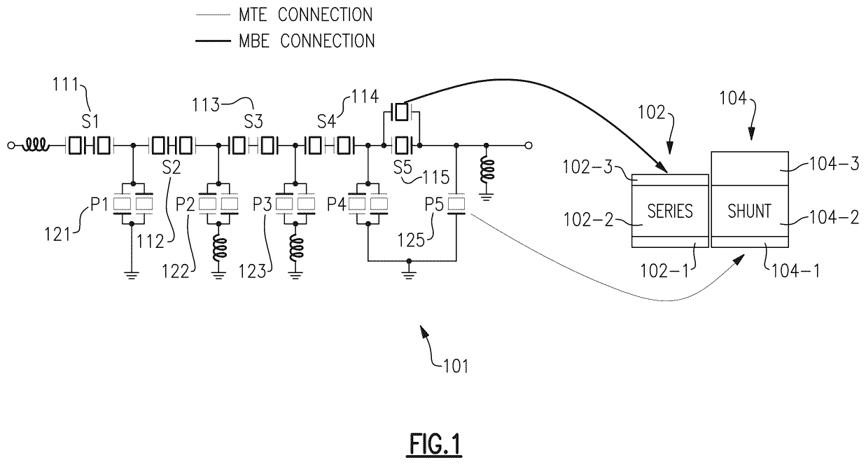

FIG. 1 illustrates an exemplary circuit diagram of a known exemplary acoustic device 102, and schematic cross-sectional diagrams of known exemplary series resonator 102 and shunt resonator 104. The acoustic device shown in FIG. 1 comprises a plurality of series resonators 111, 112, 113, 114, 115 and a plurality of shunt resonators 121, 122, 123, 124, 125.

In a number of known acoustic devices, such as the acoustic device shown in the cross-sectional diagrams of FIG. 1, one or more mass loading layers are added on the metal top electrode (MTE) 104-3 of the shunt resonator in order to separate the frequencies of the series and shunt resonators. As described above larger mass load structures in known acoustic devices are typically placed around one electrode 104-3, which corresponds to the top layer 104-3 of the shunt resonator 104 of FIG. 1. The top layer 104-3 of the shunt resonator 104 comprises a metal top electrode (MTE) and one or more mass loading (MF) layers.

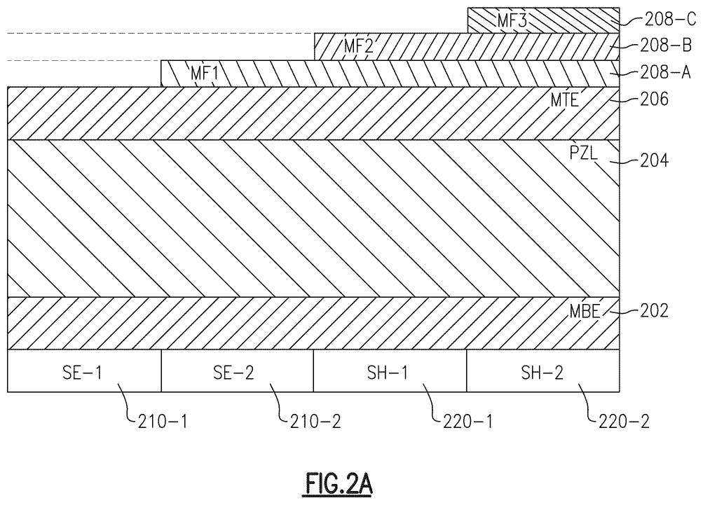

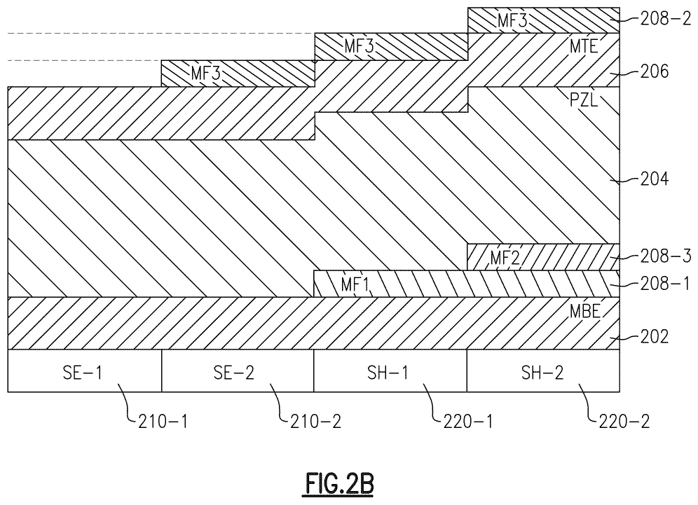

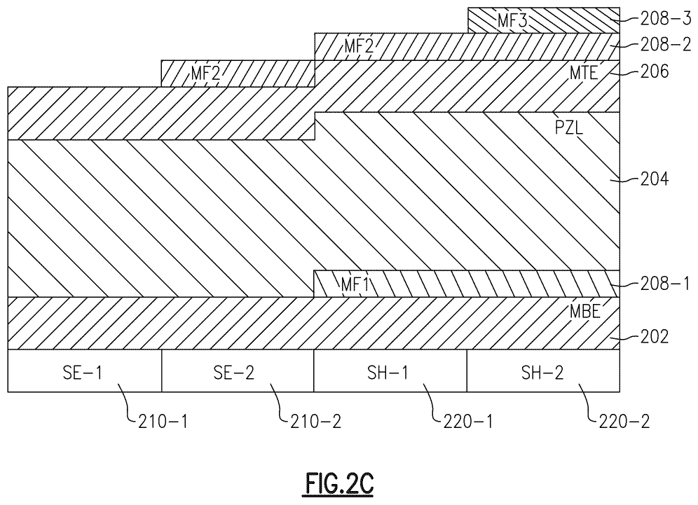

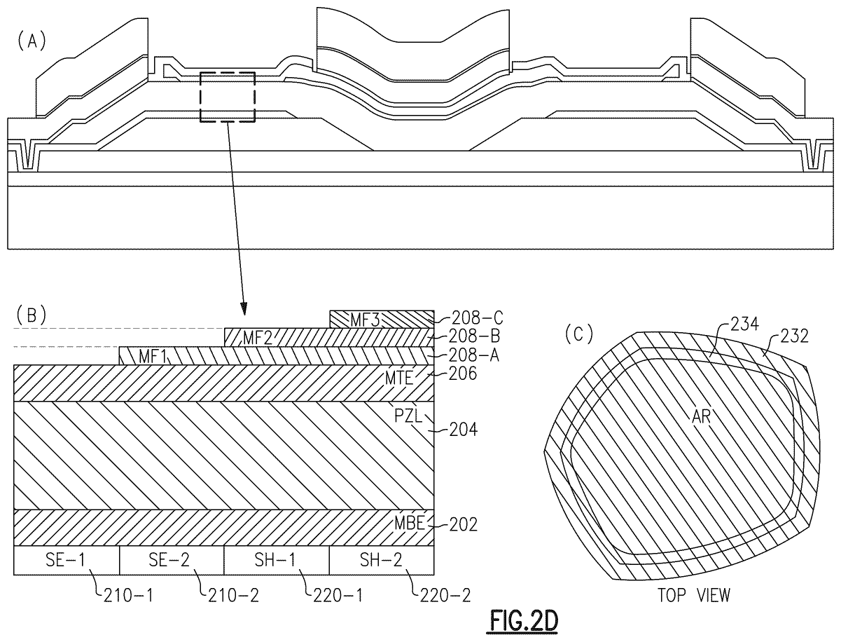

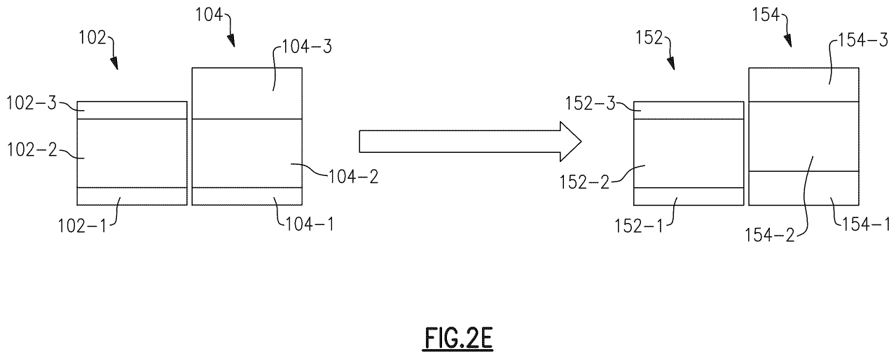

FIG. 2A is a schematic cross-sectional diagrams of an exemplary known acoustic device structure comprising series resonator sections 210-1, 210-2 and shunt resonators sections 220-1, 220-2. The structure of FIG. 2A illustrates an example of an acoustic device structure having series resonators 102 and shunt resonators 104 integrally formed therein, such as those shown in FIG. 1.

Such MTE 206 and MF layers 208-A, 208-B, 208-C are typically made of the same material, and may be in provided as a single layer (e.g. to form a thick MTE). However, such stack structures with imbalanced thicknesses of materials on either side of the piezoelectric layer 204. In other words, provided that the MTE 206 and MBE 202 are of the same thickness in the sample of FIG. 2A, the total thickness of the material on the bottom side of the piezoelectric layer 204 (“a first electrode region” or “a bottom electrode region” as used herein) differs from the total thickness of the material on the top side of the piezoelectric layer 204 (“a second electrode region” or “a top electrode region” as used herein) by the thickness of the MF layers 208-A, 208-B, 208-C. Such imbalanced structures are subject to degrading of shunt resonator performances (e.g. Q factor and/or electromechanical coupling coefficient (Kt2)). Furthermore, such structures also typically lead to high-magnitude overtone mode resonance, which may affect the performance of the carrier aggregation (CA) band filter as well as harmonic generation (e.g. 2nd (H2) and 3rd (H3) harmonics).

FIG. 2D illustrates a schematic cross-sectional diagram of an exemplary acoustic device (A). FIG. 2D also illustrates a top view (C) of the said exemplary an acoustic device. As shown in FIG. 2D, such an acoustic device may comprise one or more acoustic device structures (B), such as the known acoustic device structure of FIG. 2A. However, it will also be appreciated that one or more of the acoustic device structures according to the embodiments the described below may also be included in an acoustic device such as that of FIG. 2D.

Embodiments of the invention may provide an acoustic wave device comprising a piezoelectric layer and electrode regions having balanced thicknesses. For instance, as illustrated in the simplified example shown in FIG. 2E (right), the bottom electrode regions 152-1, 154-1 may have the same or similar thickness as the top electrode regions 152-3, 154-3, in both the series resonator section 152 and the shunt resonator section 154. This is because the MF layers are distributed in both the bottom electrode region 154-1 and the top electrode region 154-3, rather than being positioned in the top electrode region 154-3 only. As a result, in the example shown in FIG. 2E (right), the bottom electrode regions 152-1, 154-1 may have the same or similar thickness as the top electrode regions 152-3, 154-3, in both the series resonator section 152 and the shunt resonator section 154.

This is in contrast to the known, imbalanced structure shown in FIG. 1 and FIG. 2E (left) in which the bottom electrode region 104-1 of the shunt resonator section 104 does not comprise any MF layer and only the top electrode region 104-3 of the shunt resonator section 104 comprises one or more MF layers. Hence, in the example shown in FIG. 2E (right), the bottom electrode region 104-1 of the shunt resonator section 104 is of smaller thickness compared to the top electrode region 154-3 of the shunt resonator section 104.

Thus, according to a number of embodiments, acoustic wave device structure with balanced electrodes may be provided by distributing one or more first MF layers around a MBE 154-1 and one or more second MF layers around a MTE 154-3. The term “around a MBE” and “around a MTE” as used herein indicate that the corresponding MF layers may be positioned on or near the MBE 154-1 and MTB 154-3, respectively.

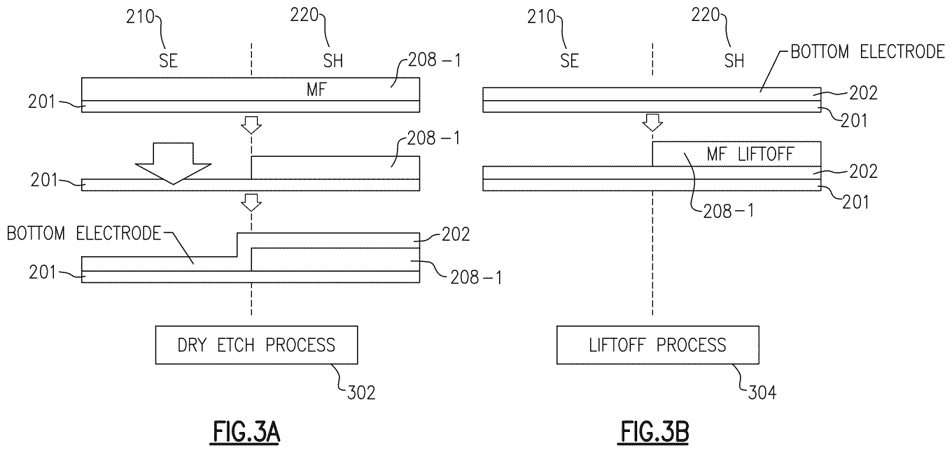

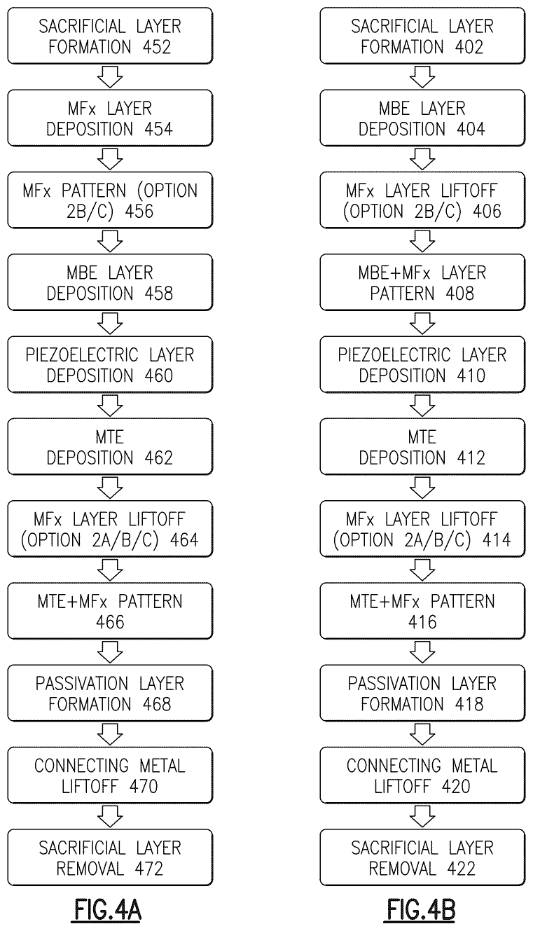

Such MBE, MTE and MF layers (154-1, 154-3, 152-1, 152-3) may be made of the same material. One or more of the MBE layers and one or more of the MF layers may be formed as a single layer. For example, in order to form a MBE layer and one or more of adjacent MF layers made of the same material, a single deposition technique and/or process may be used to form the MBE layer and the one or more of adjacent MF layers. Alternatively, the MBE, MTE and MF layers may be made of different materials. Methods for forming the acoustic device structure are discussed further in relation to FIGS. 3A-3B and FIGS. 4A-4B.

FIG. 2B is a schematic cross-sectional diagrams of an exemplary acoustic device structure comprising series resonator sections 210-1, 210-2 and shunt resonators sections 220-1, 220-2 according to an embodiment. As shown in FIG. 2B, the acoustic device structure has one or more series resonator sections 210-1, 210-2 and one or more shunt resonator sections 220-1, 220-2. In the example of FIG. 2B, the acoustic device structure comprises two series resonator sections 210-1, 210-2 and two shunt resonator sections 220-1, 220-2. However, it will be appreciated that, in other embodiments, the acoustic device structure may comprise any number of series resonator section(s) 210-1, 210-2 and any number of shunt resonator section(s) 220-1, 220-2.

As shown in the example of FIG. 2B, the series resonator section(s) 210-1, 210-2 and the shunt resonator section(s) may optionally be integrally formed. In other words, one or more of the layers of the acoustic device structure may extend over one or more of the series resonator section(s) 210-1, 210-2 and/or the shunt resonator section(s). Moreover, one or more of the series resonator section(s) 210-1, 210-2 and the shunt resonator section(s) may optionally be formed on a single substrate or a platform. In such cases, said substrate may be removed from the acoustic device structure during or after fabrication.

As shown in the example of FIG. 2B, the acoustic device structure comprises a first electrode layer 202 extending across the one or more series resonator sections 210-1, 210-2 and the one or more shunt resonator sections 220-1, 220-2. In the example of FIG. 2B, the first electrode layer 202 extends across all of the series resonator sections 210-1, 210-2 and the shunt resonator sections 220-1, 220-2.

Similarly, the acoustic device structure comprises a second electrode layer 206 extending across the one or more series resonator sections 210-1, 210-2 and the one or more shunt resonator sections 220-1, 220-2. In the example of FIG. 2B, the second electrode layer 206 extends across all of the series resonator sections 210-1, 210-2 and the shunt resonator sections 220-1, 220-2.

As shown in the example of FIG. 2B, the first electrode layer 202 may be provided in the forms of a MBE, and the second electrode layer 206 may be provided in the form of a MTE.

Furthermore, as shown in the example of FIG. 2B, the acoustic device structure comprises a piczoelectric layer 204 extending across the one or more series resonator sections 210-1, 210-2 and the one or more shunt resonator sections 220-1, 220-2. In the example of FIG. 2B, the piezoelectric layer 204 extends across all of the series resonator sections 210-1, 210-2 and the shunt resonator sections 220-1, 220-2. The piezoelectric layer 204 is positioned between the first electrode layer 202 and the second electrode layer 206. Thus, as shown in the example of FIG. 2B, the piezoelectric layer 204 may have a first side in physical contact with the first electrode layer 202 and a second side in physical contact with the second electrode layer 206.

In a number of known acoustic devices, such as the acoustic device shown in the cross-sectional diagrams of FIG. 1, the mass loading layers 208 for separating the frequencies of the series and shunt resonators are positioned on the MTE 106 only. In contrast, the acoustic device structure comprises a first mass loading layer (the first MF layer) 208-1 extending across at least the one or more shunt resonator sections 220-1, 220-2 and a second mass loading layer (the second MF layer) 208-2 extending across at least the one or more shunt resonator sections 220-1, 212-2 and at least one 210-2 of the one or more series resonator sections 210-1, 210-2. Thus, the first mass loading layer 208-1 is positioned between the first electrode layer 202 and the piezoelectric layer 204, and the second electrode layer 206 is positioned between the piezoelectric layer 204 and the second mass loading layer 208-2. In the example of FIG. 2B, the first MF layer extends across all of the shunt resonator sections 220-1, 220-2, and the second MF layer extends across all of the shunt resonator sections 220-1, 220-2 and one 210-2 of the series resonator sections.

As a result, the acoustic wave device structure provides a more balanced electrodes structure in which the MF layer(s) 208-1, 208-2 are not only located around only one of the electrode layers (i.e. in the acoustic wave device, one or more first MF layers are positioned around the first electrode layer 202 and one or more second MF layers are positioned around the second electrode layer 206). Consequently, the thickness of the two electrode regions facing the opposite sides of the piezoelectric layer 204 may be more closely matched, whilst achieving the desired effect of separating the frequencies of the series and shunt resonator sections. For the avoidance of doubt, the MF layers of each of the series and shunt resonator sections (210-1, 210-2, 220-1, 220-2) may have different total thicknesses.

In the example of FIG. 2B, the first shunt resonator section 220-1 comprises the first electrode region having the MBE 202 and the first MF layer 208-1, and the second electrode region having the MTE 206 and the second MF layer 208-2. Therefore, in the example of FIG. 2B, the thickness of the first electrode region of the first shunt resonator section 220-1 equates to the sum of the thicknesses of the MBE layer 202 and the first MF layer 208-1. Similarly, in the example of FIG. 2B, the thickness of the second electrode region of the first shunt resonator section 220-1 equates to the sum of the thicknesses of the MTE layer 206 and the second MF layer 208-2. Therefore, the thicknesses of the MBE layer 202, the first MF layer 208-1, the MTE layer 206, and the second MF layer 208-2 may be determined so as to achieve a balanced structure. For example, they may be selected so that the thickness of the first electrode region 202, 208-1 within at least one of the one or more shunt resonator sections 220-1, 220-2 and the thickness of the second electrode region 206, 208-2 within at least one of the one or more shunt resonator sections 220-1, 220-2 are identical. Alternatively, the thickness of the first electrode region 202, 208-1 within at least one of the one or more shunt resonator sections 220-1, 220-2 and the thickness of the second electrode region 206, 208-2 within at least one of the one or more shunt resonator sections 220-1, 220-2 may be substantially the same. For example, the thicknesses may differ by less than 30%, however, it will be appreciated that the maximum difference between the thicknesses may differ depending on one or more materials and layout of the acoustic device structure.

Optionally, the electrode layer 202 and the first MF layer 208-1 may be made of the same conductive material. Alternatively, the first electrode layer 202 and the first MF layer 208-1 may optionally be made of different conductive materials.

Similarly, the second electrode layer 206 and the second MF layer 208-2 may optionally be made of the same conductive material. Alternatively, the second electrode layer 206 and the second MF layer 208-2 may optionally be made of different conductive materials.

Optionally, the first electrode region 202, 208-1 and the second electrode region 206, 208-2 may be made of the same conductive material. Alternatively, the first electrode region 202, 208-1 and the second electrode region 206, 208-2 may optionally be made of different conductive materials.

It will be appreciated that using one or more of the conductive components (e.g. the MF layers 208-1, 208-2, 208-3 and the electrode layers 202, 206) with the same conductive material may have advantages such as ease of fabrication. However, it will be also appreciated that, in some cases, it may be desirable to use different materials for different conductive components in order to utilize electrical, mechanical, optical and/or acoustic properties of multiple materials.

Optionally, one or more of the conductive components 208-1, 208-2, 208-3, 202, 206 may be made of or comprise one or more materials having high acoustic impedance. For example, the one or more of the conductive components 208-1, 208-2, 208-3, 202, 206 may be made of or comprise one or more materials having acoustic impedance of at least 30 MRayl. For example, the conductive components 208-1, 208-2, 208-3, 202, 206 may be made of or comprise one or more of: W, Ru, Mo, Ir, Os, Pt, Re and any other materials having a higher acoustic impedance than 30 Mrayls. Table 1 provides a list of example high-impedance materials having acoustic impedance of at least 30 MRayl, and their material properties.

TABLE 1
Table of example high-impedance materials
and their material properties.

| High | Acoustic | Melting | Bulk | |
|---|---|---|---|---|
| Impedance | Impedance | Point | Resistivity | Lattice |
| Metals | [MRayls] | [° C.] | [μΩcm] | Type |
| W | 100 | 3422 | 5 | bcc |
| Ru | 82 | 2334 | 7 | hex |
| Mo | 66 | 2623 | 5 | bcc |
| Ir | 109 | 2446 | 4.71 | fcc |
| Os | 111 | 3033 | 8.12 | hex |
| Pt | 60 | 1768 | 10.5 | fcc |
| Re | 98 | 3186 | 19.3 | hex |

Optionally, the acoustic wave device structure may further comprise a third mass loading layer (the third MF layer) 208-3. The third MF layer 208-3 may form a part of the first electrode region (e.g. as shown in FIG. 2B) or the second electrode region (e.g. as shown in FIG. 2C). The third MF layer 208-3 may extend across at least one 220-2 of the one or more shunt resonator sections 220-1, 220-2.

As shown in the example of FIG. 2B, the third MF layer 208-3 may be positioned between the first MF layer 208-1 and the piezoelectric layer 204. Thus, the first electrode region 202, 208-1, 208-3 of the acoustic wave device in the example of FIG. 2B comprises the first electrode layer 202, the first MF layer 208-1 and the third MF layer 208-3; and the second electrode region 206, 208-2 of the acoustic wave device in the example of FIG. 2B comprises the second electrode layer 206 and the second MF layer 208-2.

As the third MF layer 208-3 is an optional component, some embodiments of the acoustic wave device may only comprise the first and second MF layers 208-1, 208-2. In such cases, the first electrode region 202, 208-1 of the acoustic wave device may comprise the first electrode layer 202 and the first MF layer 208-1, and the second electrode region 206, 208-2 may comprise the second electrode layer 206 and the second MF layer 208-2.

Alternatively, the optional third MF layer 208-3 may be located in a different position, such as on or within the second electrode region. FIG. 2C illustrates an example of such alternative embodiments. The acoustic device structure shown in FIG. 2C is similar to that of FIG. 2B, except that the third MF layer 208-3 of FIG. 2C is located on the distal side of the second electrode region. Consequently, its second MF layer 208-2 is positioned between the second electrode layer 206 and third MF layer 208-3.

Thus, the first electrode region 202, 208-1 of the acoustic wave device in the example of FIG. 2C comprises the first electrode layer 202 and the first MF layer 208-1; and the second electrode region 206, 208-2, 208-3 of the acoustic wave device in the example of FIG. 2C comprises the second electrode layer 206, the second MF layer 208-2, and the third MF layer 208-3.

Furthermore, due to the different positions of the third MF layer 208-3 in the examples of FIG. 2B and FIG. 2C, the thickness of the first electrode region throughout the shunt resonator regions 220-1, 220-2 of the example of FIG. 2C is uniform. This is in contrast to the example of FIG. 2B wherein the thickness of the first electrode region in the first shunt resonator region 220-1 is smaller than that in the second shunt resonator region 220-2.

The different positions of the third MF layer 208-3 in the examples of FIG. 2B and FIG. 2C also means that, in the example of FIG. 2B, the thickness of the second electrode region in the first shunt resonator region 220-1 is smaller than that in the second shunt resonator region 220-2. This is in contrast to the example of FIG. 2C wherein the thickness of the second electrode region throughout the shunt resonator regions 220-1, 220-2 is uniform.

It will be appreciated that some embodiments of the acoustic device structure may comprise three or more MF layers. In such cases, the third 208-3 and onward MF layers needs to be taken into account when determining the thickness of the corresponding electrode region(s) of the corresponding section(s) 210, 220. Furthermore, the third 208-3 and onward MF layers may optionally be made of the same conductive material as one or more of the other conductive components. Alternatively, one or more of the third 208-3 and onward MF layers may be made of different conductive materials.

As discussed above, the acoustic wave device structure comprises one or more electrode layers and one or more mass loading layers. FIG. 3A and FIG. 3B illustrates how such one or more electrode layers and one or more mass loading layers may be formed to manufacture the acoustic wave device structure.

FIG. 3B illustrates how the first mass loading layer 208-1 and the first electrode layer 202 may be formed. As shown in FIG. 3B, the first electrode layer 202 is formed on a substrate 201. The acoustic device structure has two or more sections 210, 220, such as the series resonator section 210 and the shunt resonator section 220 described above, and the first electrode layer 202 extends across at least a first section 210 and a second section 220 of the two or more sections 210, 220. For examples, the first electrode layer 202 may extend across at least one series resonator section 210 and at least one shunt resonator section 220.

As shown in FIG. 3B, a first mass loading layer 208-1 is formed on the first electrode layer 202 so that the first electrode layer 202 extends across the second section (220). For examples, as described above the first electrode layer 202 may extend across at least one shunt resonator section 220.

Following the formation of the first electrode layer 202 and the first mass loading layer 208-1 as illustrated in FIG. 3B, a piezoelectric layer 204 may be formed on the first electrode layer 202 and the first mass loading layer 208-1 so that the piezoelectric layer 204 extends across the first section 210 and the second section 220, and is in contact with the first electrode layer 202 in the first section 210 and with the first mass loading layer 208-1 in the second section 220. For example, as described above, the piezoelectric layer 204 may extend across the at least one series resonator section 210 and at least one shunt resonator section 220, and may be in contact with the first electrode layer 202 in the series resonator section 210 and with the first mass loading layer 208-1 in the shunt resonator section 220.

Once the piezoelectric layer 204 has been formed, a second electrode layer 206 may be formed on the piezoelectric layer 204. Similarly, once the second electrode layer 206 has been formed, a second mass loading layer 208-2 may be formed on the second electrode layer 206. For example, as described above, the second electrode layer 206 may extend across at least one shunt resonator section (220).

Although the example of FIG. 3B relates to the formation of the first mass loading layer 208-1 and the first electrode layer 202, it will be appreciated that the same techniques may also be used to form one or more electrode layers and one or more mass loading layers included in other part(s) of the acoustic wave device structure. Furthermore, although the example of FIG. 3B relates to a process involving lift-off techniques, it will be appreciated that other suitable techniques such as etching and/or milling may also be used in other embodiments.

When the etching process is used to form the first mass loading layer 208-1, any suitable etching techniques, such as a dry etching technique may be used. For example, the step of forming the first mass loading layer 208-1 may be performed by depositing an initial layer of material(s) forming the first mass loading layer 208-1 across the first section 210 and the second section (220), and performing the etching process to remove the initial layer of material(s) from the first section 210.

Alternatively, when the lift-off process is used to form the first mass loading layer 208-1, any suitable lift-off techniques, such as one or more photolithography techniques may be used. For example, the step of forming the first mass loading layer 208-1 may be performed by depositing an initial layer of material(s) forming the first mass loading layer 208-1 across the first section 210 and the second section 220, and performing the lift-off process to remove the initial layer of material(s) from the first section 210.

One or more parts of the acoustic device structure is formed on a substrate (e.g. as shown in the example of FIG. 3B), such a substrate 201 may be removed from the acoustic device structure during or after the manufacturing process. For example, the substrate 201 may be removed by means of milling and/or lift-off. Optionally, in order to assist such milling and/or lift-off processes, the acoustic device structure may comprise one or more sacrificial layers for the milling, lift-off and/or etching. Optionally, such sacrificial layer(s) may also be removed during or after the manufacturing process.

For the acoustic wave device structure with the third mass loading layer 208-3, the manufacturing method may further comprise the step of forming a third mass loading layer 208-3. As described above, third mass loading layer 208-3 may extend across at least a part 220-2 of the second section 220. The third mass loading layer 208-3 may, for example, be formed after the step of forming the first mass loading layer 208-1 to be positioned between the first mass loading layer 208-1 and the piezoelectric layer 204. Alternatively, the third mass loading layer 208-3 may be formed after the step of forming the second electrode layer 206 so that the second electrode layer 206 is positioned between the piezoelectric layer 204 and the third mass loading layer 208-3.

It will be appreciated that the manufacturing method may be modified or extended in order to form an acoustic wave device comprising the acoustic wave device structure. For example, the method may be modified or extended to further include a step of forming one or more acoustic wave device components on the acoustic device structure. Such acoustic wave device component(s) may be: one or more resonator structures, one or more bulk acoustic wave device components, one or more electrical connections, and/or one or more cavity packages.

In contrast to the example of FIG. 3B, the first third mass loading layer 208-1 may be formed prior to the formation of the first electrode layer 202. In such cases, as shown in FIG. 3A, the first electrode layer 202 is formed on the substrate 201 so that and the first mass loading layer 208-1 extends across the second section 220 of the two or more sections 210, 220.

The first electrode layer 202 is then formed on the substrate 201 and the first mass loading layer 208-1. In this way, the first electrode layer 202 is formed so that it extends across the first section 210 and the second section 220, and it is in contact with the substrate 201 in the first section 210, and with the first mass loading layer 208-1 in the second section 220.

The piezoelectric layer 204, in such cases, is formed on the first electrode layer 202 so that the piezoelectric layer 204 extend across the first section 210 and the second section 220, and it is in contact with the first electrode layer 202 in the first section 210 and the second section 220.

It will be appreciated that, except for the formation of the first mass loading layer 208-1, first electrode layer 202, and the piezoelectric layer 204, other optional steps and/or features of the embodiments discussed in relation to FIG. 3B are applicable to the alternative embodiments discussed in relation to FIG. 3A.

FIGS. 4A and 4B illustrates exemplary steps for manufacturing the acoustic wave device structure according to an embodiment. As shown in the example flow diagram of FIG. 4A, when manufacturing the acoustic wave device structure using dry-etch process, the first mass loading layer 208-1 may be formed 454 prior to forming 458 the MBE layer 202. The first mass loading layer 208-1 may be formed on a substrate. 201. Optionally, one or more of the sacrificial layer may be formed 452 prior to the deposition of the first mass loading layer 208-1. In such cases, the sacrificial layer may be formed on a substrate. Optionally, prior to forming 458 the MBE layer 202, patterning 456 may be performed on the first mass loading layer 208-1. Once the first mass loading layer 208-1 and the MBE layer 202 have been formed, the piezoelectric layer 204 may be formed 460, on which the MTE layer 206 may be formed 462. One or more additional mass loading layers may also be formed on the MTE layer 206 by using liftoff 464 techniques. Optionally, patterning 466 may be performed on the additional mass loading layer(s) and the MTE layer 204. Once the acoustic wave device structure has been formed, optionally, a passivation layer may be formed on one or more surfaces 468 of the acoustic wave device. Optionally, one or more connecting metal lift-off 470 and/or removal 472 of the sacrificial layers may also be performed.

FIG. 4B shows another example flow diagram wherein the acoustic wave device structure is manufactured using lift-off techniques. In contrast to the example of FIG. 4A, the first mass loading layer 208-1 may be formed after forming 404 the MBE layer 202. The MBE layer 202 may be formed on a substrate. 201. Optionally, one or more of the sacrificial layer may be formed 452 prior to the deposition of the MBE layer 202. In such cases, the sacrificial layer may be formed on a substrate. The first mass loading layer 208-1 may be formed using lift-off techniques 406. Once the first mass loading layer 208-1 and the MBE layer 202 have been formed, the piezoelectric layer 204 may be formed 410, on which the MTE layer 206 may be formed 412. One or more additional mass loading layers may also be formed on the MTE layer 206 by using liftoff 414 techniques. Optionally, patterning 416 may be performed on the additional mass loading layer(s) and the MTE layer 204. Once the acoustic wave device structure has been formed, optionally, a passivation layer may be formed on one or more surfaces 418 of the acoustic wave device. Optionally, one or more connecting metal lift-off 420 and/or removal 422 of the sacrificial layers may also be performed.

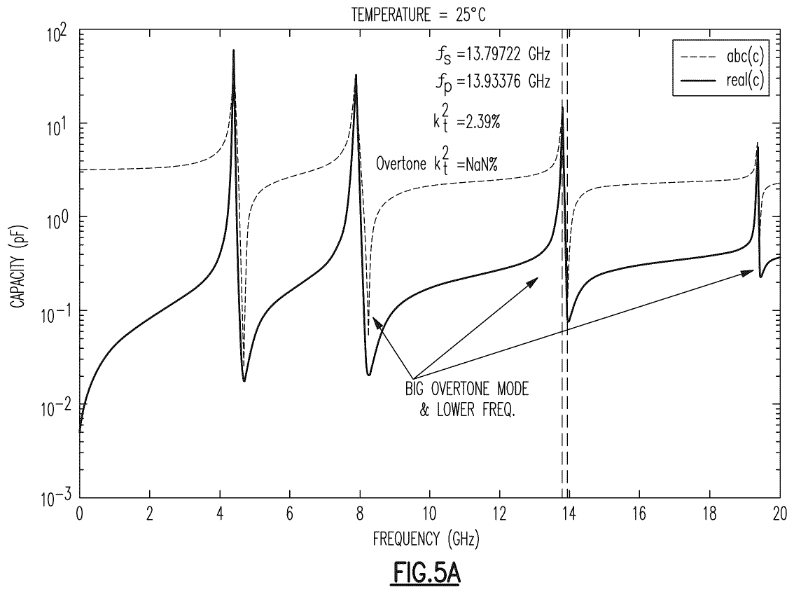

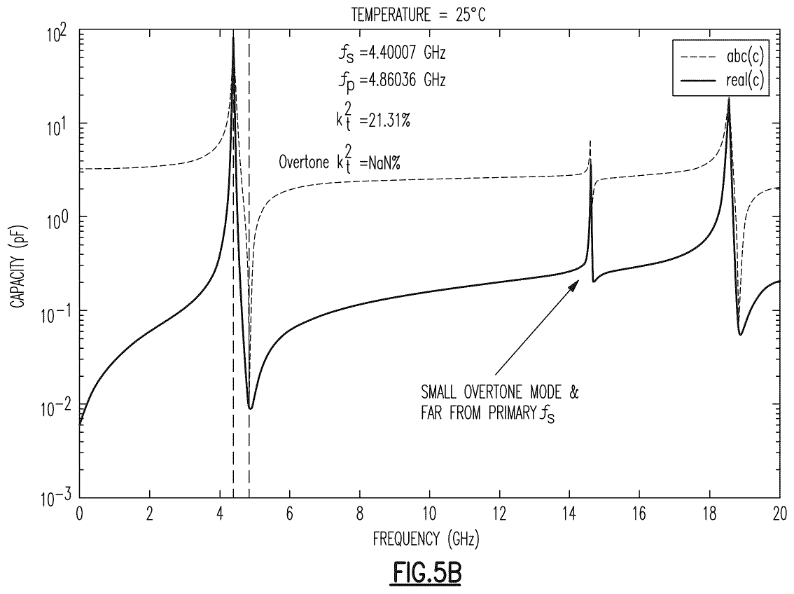

FIG. 5A is a capacity vs frequency plot illustrating overtone modes of a known exemplary acoustic wave device. Table 2 provide details of materials and thicknesses of layers of the known device and corresponding Kt2 values (“Known (Se)” column corresponds to the values of the known device in the series resonator section, “Known (Sh)” column corresponds to the values of the known device in the shunt resonator section, and x indicates that the corresponding layer is not present). The “layer” column, except for the Kt2(%) row, shows the layers in order (i.e. the known device has a “Bottom electrode” at the bottom and a “Mass load (MF)” layer at the top).

TABLE 2
Table of materials and thicknesses of layers of a known acoustic device and
an acoustic device according to an embodiment, and corresponding Kt2 values.

| | | Known (Se) | Known (Sh) | New (Se) | New (Sh) |
|---|---|---|---|---|---|
| Layer | Material | Thick (nm) | Thick (nm) | Thick (nm) | Thick (nm) |
| Mass load (MF) | Ru | x | 370.376 | x | 103 |
| Top electrode | Ru | 63 | 63 | 63 | 63 |
| Piezoelectric | AlN | 200 | 200 | 200 | 200 |
| Mass load (MF) | Ru | x | x | x | 95 |
| Bottom electrode | Ru | 63 | 63 | 63 | 63 |
| Kₜ²(%) | | 24% | 12.0% | 24% | 21.4% |

As shown in FIG. 5A, such a known device, having a MF layer only on or near one side of its structure, is subject to high-magnitude overtone mode resonances of high numbers, which may affect the performance of the device (e.g. degraded CA band filter performance and harmonic generation (e.g. 2nd (H2) and 3rd (H3) harmonics)).

FIG. 5B is a capacity vs frequency plot illustrating overtone modes of an acoustic device according to an embodiment. Table 2 also provide details of materials and thicknesses of layers of the acoustic device according and corresponding Kt2 values (“New (Se)” column corresponds to the values of the device in the series resonator section, “New (Sh)” column corresponds to the values of the device in the shunt resonator section, and x indicates that the corresponding layer is not present). The “layer” column, except for the Kt2(%) row, shows the layers in order (i.e. the known device has a “Bottom electrode” at the bottom and a “Mass load (MF)” layer at the top).

In contrast to FIG. 5A, FIG. 5B shows that the acoustic device, of which MF layers are distributed on or near both sides of its structure, display significantly reduced magnitude of overtone mode resonances, thereby improving the device performance. In comparison to the example of FIG. 5A, FIG. 5A also displays smaller number of overtone mode resonances.

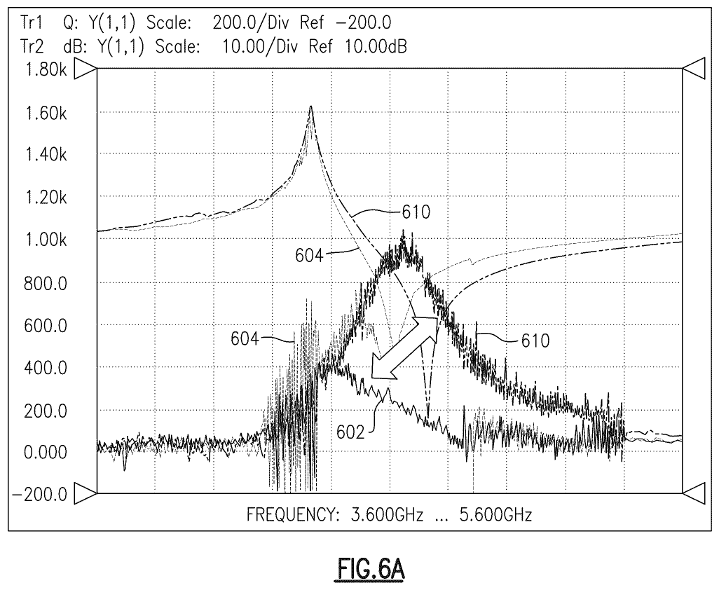

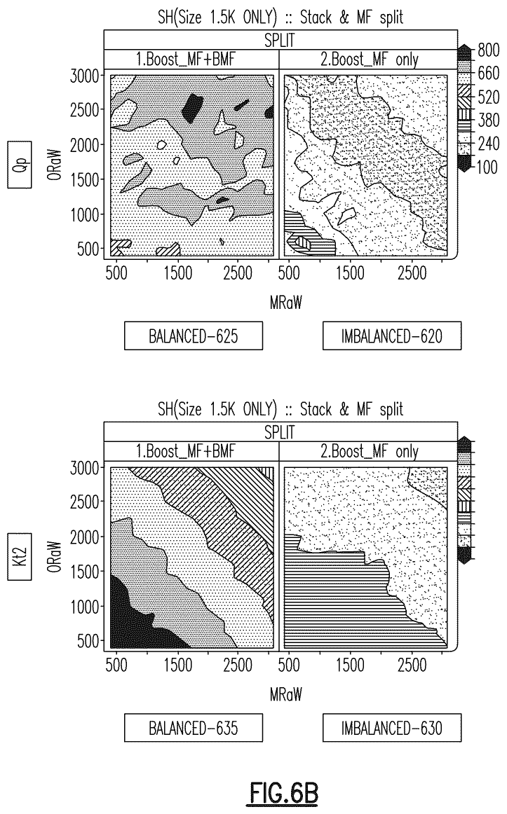

FIG. 6A illustrates Q (top) and Kt2 (bottom) of an exemplary acoustic wave device 610 according to an embodiment and known exemplary acoustic wave devices 604, 610. As shown in FIG. 6A, the acoustic wave device 610, having MF layers distributed on or near both sides of its structure, display significantly improved Q and Kt2, compared to the known exemplary acoustic wave devices 604, 610, having a MF layer only on or near one side of its structure. FIG. 6B provides visual illustrations showing the contrast in Q and Kt2 between the acoustic wave device according to an embodiment, having MF layers distributed on or near both sides of its structure, and a known acoustic wave device having a MF layer only on or near one side of its structure.

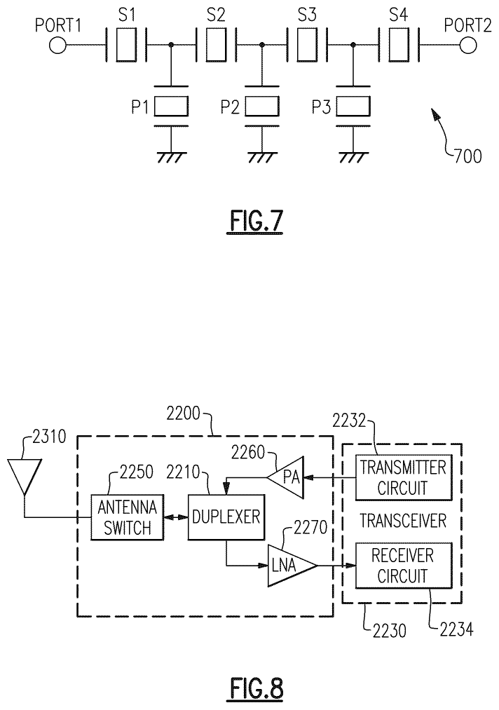

FIG. 7 is a filter 700 according to aspects of the present invention. The filter 700 comprises a plurality of BAW resonators. One or more the plurality of BAW resonators comprises electrodes with balanced thickness, such as those shown in the examples of FIGS. 2B and 2C. The filter 700 is a passband or ladder filter, though it will be appreciated that the BAW resonators described herein can be included in other types of filter.

The ladder filter 700 includes a plurality of series resonators S1, S2, S3, and S4 coupled in series between an input port, PORT1, and an output port, PORT2. The filter 700 also includes a plurality of parallel resonators P1, P2, and P3 connected between terminals of the series resonators and ground. Whilst four series resonators S1, S2, S3, S4 and three parallel resonators P1, P2, P3 are shown, it will be appreciated that more or fewer series and/or parallel resonators may be used.

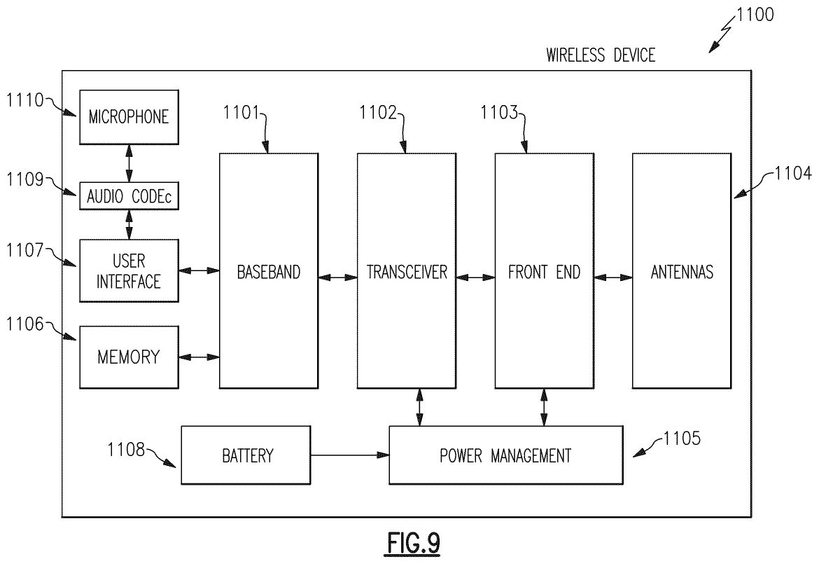

The filter 700 of FIG. 7, or the BAW resonators comprising electrodes with balanced thickness, such as those shown in the examples of FIGS. 2B and 2C, may also be included in a radio-frequency front end (RFFE) module. An exemplary RFFE module is shown in FIG. 8. This figure illustrates a front end module 2200, connected between an antenna 2310 and a transceiver 2230. The front end module 2200 includes a duplexer 2210 in communication with an antenna switch 2250, which itself is in communication with the antenna 2310.

As illustrated, the transceiver 2230 comprises a transmitter circuit 2232. Signals generated for transmission by the transmitter circuit 2232 are received by a power amplifier (PA) module 2260 within the front end module 220 which amplifies the generated signals from the transceiver 2230. The PA module 2260 can include one or more Pas. The PA module 2260 can be used to amplify a wide variety of RF or other frequency-band transmission signals. For example, the PA module 2260 can receive an enable signal that can be used to pulse the output of the PE to aid in transmitting a wireless local area network (WLAN) signal or any other suitable pulsed signal. The PA module 2260 can be configured to amplify any of a variety of types of signal, including, for example, a Global System for Mobile (GSM) signal, a code division multiple access (CDMA) signal, a W-CDMA signal, a Long Term Evolution (LTE) signal, or an EDGE signal. In certain embodiments, the PA module 2260 and associated components including switches and the like can be fabricated on gallium arsenide (GaAs) substrates using, for example, high electron mobility transistors (pHEMT) or insulated-gate bipolar transistors (BiFET), or on a silicon substrate using complementary metal-oxide semiconductor (CMOS) field effect transistors (FETs).

Still referring to FIG. 8, the front end module 2200 may further include a low noise amplifier (LNA) module 2270, which amplifies received signals from the antenna 2310 and provides the amplified signals to the receiver circuit 2234 of the transceiver 2230.

FIG. 9 is a schematic diagram of a wireless device 1100 that can incorporate aspects of the invention. The wireless device 1100 can be, for example but not limited to, a portable telecommunication device such as, a mobile cellular-type telephone. The wireless device 1100 can include a microphone arrangement 1100, and may include one or more of a baseband system 1101, a transceiver 1102, a front end system 1103 (such as the front end module 2200 of FIG. 8), one or more antennas 1104, a power management system 1105, a memory 1106, a user interface 1107, a battery 1108, and audio codec 1109. The microphone arrangement may supply signals to the audio codec 109 which may encode analog audio as digital signals or decode digital signals to analog. The audio codec 1109 may transmit the signals to a user interface 1107. The user interface 1107 transmits signals to the baseband system 1101. The transceiver 1102 generates RF signals for transmission and processes incoming RF signals received from the antennas. The front end system 1103 aids in conditioning signals transmitted to and/or received from the antennas 1104. The antennas 1104 can include antennas used for a wide variety of types of communications. For example, the antennas 1104 can include antennas 1104 for transmitting and/or receiving signals associated with a wide variety of frequencies and communications standards. The baseband system 1101 is coupled to the user interface to facilitate processing of various user input and output, such as voice and data. The baseband system 1101 provides the transceiver 1102 with digital representations of transmit signals, which the transceiver 1102 processes to generate RF signals for transmission. The baseband system 1101 also processes digital representations of received signals provided by the transceiver 1102.

As shown in FIG. 9, the baseband system 1101 is coupled to the memory 1106 to facilitate operation of the wireless device 1100. The memory 1106 can be used for a wide variety of purposes, such as storing data and/or instructions to facilitate the operation of the wireless device 1100 and/or to provide storage of user information. The power management system 1105 provides a number of power management functions of the wireless device 1100. The power management system 1105 receives a battery voltage from the battery 1108. The battery 1108 can be any suitable battery for use in the wireless device, including, for example, a lithium-ion battery.

The BAW resonators described herein, such as those described with respect to FIG. 7, or the BAW resonators comprising electrodes with balanced thickness, such as those shown in the examples of FIGS. 2B and 2C, may be incorporated onto one or more dies used within the wireless device 1100. In particular, a die incorporating BAW resonators according to the present disclosure may be incorporated into a radio-frequency module (such as radio-frequency front end module 1103) which may be incorporated into the wireless device 1100. The BAW resonators may be incorporated into a number of different components which may be incorporated into the wireless device 100, including but not limited to various forms of filters and duplexers.

The piezoelectric layers of the acoustic devices described herein may have been described with respect to a specific example, though it will be appreciated that other compositions of piezoelectric layer may be used. The required piezoelectric material will be based upon, amongst other considerations, the desired frequency range of operation of the acoustic device. A non-exhaustive list of possible piezoelectric materials includes aluminium nitride (AlN), doped aluminium nitride, lithium niobate (LiNbO3), lithium tantalate (LiTaO3), lead titanate (PbTiO3), and zirconium titanate (ZrTiO3).

Similarly, a variety of materials may be used for the top and bottom electrodes in each of the embodiments described herein. Preferably, the top and bottom electrodes are formed from a material having a high acoustic impedence. Preferably, the top and bottom electrodes are formed from the same material. Suitable materials include, but are not limited to, tungsten (W), ruthenium (Ru), molybdenum (Mo), iridium (Ir), osmium (Os), platinum (Pt), rhenium (Re), aluminum (Al), copper (Cu), palladium (Pd), and beryllium (Be).

Having described above several aspects of at least one embodiment, it is to be appreciated that various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

Further examples of the electronic devices that aspects of this disclosure may be implemented include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. An acoustic wave device structure, the acoustic wave device structure comprising:
one or more series resonator sections and one or more shunt resonator sections;
a first electrode layer extending across the one or more series resonator sections and the one or more shunt resonator sections;
a second electrode layer extending across the one or more series resonator sections and the one or more shunt resonator sections;
a piezoelectric layer extending across the one or more series resonator sections and the one or more shunt resonator sections, the piezoelectric layer being positioned between the first electrode layer and the second electrode layer;
a first mass loading layer extending across at least the one or more shunt resonator sections, the first mass loading layer being positioned between the first electrode layer and the piezoelectric layer; and
a second mass loading layer extending across at least the one or more shunt resonator sections and at least one of the one or more series resonator sections, the second electrode layer being positioned between the piezoelectric layer and the second mass loading layer.

2. The acoustic wave device structure of claim 1 further comprising a third mass loading layer extending across at least one of the one or more shunt resonator sections, the third mass loading layer being positioned between the first mass loading layer and the piezoelectric layer.

3. The acoustic wave device structure of claim 1 further comprising a third mass loading layer extending across at least one of the one or more shunt resonator sections, the second mass loading layer being positioned between the second electrode layer and third mass loading layer.

4. The acoustic wave device structure of claim 1 wherein a first electrode region of the acoustic wave device includes the first electrode layer and the first mass loading layer, and a second electrode region of the acoustic wave device includes the second electrode layer and the second mass loading layer.

5. The acoustic wave device structure of claim 4 wherein the thickness of the first electrode region within at least one of the one or more shunt resonator sections and the thickness of the second electrode region within at least one of the one or more shunt resonator sections are identical, or differ by less than 30%.

6. The acoustic wave device structure of claim 1 wherein the first electrode layer and the first mass loading layer are made of the same conductive material.

7. The acoustic wave device structure of claim 1 wherein the first electrode layer and the first mass loading layer are made of different conductive materials.

8. The acoustic wave device structure of claim 1 wherein the second electrode layer and the second mass loading layer are made of the same conductive material.

9. The acoustic wave device structure of claim 1 wherein the second electrode layer and the second mass loading layer are made of different conductive materials.

10. The acoustic wave device structure of claim 4 wherein the first electrode region and the second electrode region are made of the same conductive material.

11. The acoustic wave device structure of claim 4 wherein the first electrode region and the second electrode region are made of different conductive materials.

12. The acoustic wave device structure of claim 4 wherein one or more of the first electrode layer, the first mass loading layer, the second electrode layer, and the second mass loading layer include one or more materials having acoustic impedance of at least 30 MRayl.

13. The acoustic wave device structure of claim 4 wherein one or more of the first electrode layer, the first mass loading layer, the second electrode layer, and the second mass loading layer include one or more of: W, Ru, Mo, Ir, Os, Pt, Re and any other materials having a higher acoustic impedance than 30 Mrayls.

14. The acoustic wave device structure of claim 2 wherein a first electrode region of the acoustic wave device includes the first electrode layer, the first mass loading layer and the third mass loading layer; and a second electrode region of the acoustic wave device includes the second electrode layer and the second mass loading layer.

15. The acoustic wave device structure of claim 14 wherein the first electrode region within at least one of the one or more shunt resonator sections and the thickness of the second electrode region within at least one of the one or more shunt resonator sections are identical, or differ by less than 30%.

16. The acoustic wave device structure of claim 2 wherein one or more of the first electrode layer, the first mass loading layer, the second electrode layer, and the second mass loading layer are made of the same conductive material.

17. The acoustic wave device structure of claim 2 wherein one or more of the first electrode layer, the first mass loading layer, the second electrode layer, and the second mass loading layer are made of different conductive materials.

18. The acoustic wave device structure of claim 2 wherein one or more of the first electrode layer, the first mass loading layer, the second electrode layer, and the second mass loading layer include one or more materials having acoustic impedance of at least 30 MRayl.

19. A filter comprising one or more bulk acoustic wave resonators, each bulk acoustic wave resonator comprising:
one or more series resonator sections and one or more shunt resonator sections;
a first electrode layer extending across the one or more series resonator sections and the one or more shunt resonator sections;
a second electrode layer extending across the one or more series resonator sections and the one or more shunt resonator sections;
a piezoelectric layer extending across the one or more series resonator sections and the one or more shunt resonator sections, the piezoelectric layer being positioned between the first electrode layer and the second electrode layer;
a first mass loading layer extending across at least the one or more shunt resonator sections, the first mass loading layer being positioned between the first electrode layer and the piezoelectric layer; and
a second mass loading layer extending across at least the one or more shunt resonator sections and at least one of the one or more series resonator sections, the second electrode layer being positioned between the piezoelectric layer and the second mass loading layer.

20. A radio-frequency module comprising:
a packaging substrate configured to receive a plurality of devices; and
a die mounted on the packaging substrate, the die having a bulk acoustic wave resonator, the bulk acoustic wave resonator including: one or more series resonator sections and one or more shunt resonator sections; a first electrode layer extending across the one or more series resonator sections and the one or more shunt resonator sections; a second electrode layer extending across the one or more series resonator sections and the one or more shunt resonator sections; a piezoelectric layer extending across the one or more series resonator sections and the one or more shunt resonator sections, the piezoelectric layer being positioned between the first electrode layer and the second electrode layer; a first mass loading layer extending across at least the one or more shunt resonator sections, the first mass loading layer being positioned between the first electrode layer and the piezoelectric layer; and a second mass loading layer extending across at least the one or more shunt resonator sections and at least one of the one or more series resonator sections, the second electrode layer being positioned between the piezoelectric layer and the second mass loading layer.
